(19) United States
(12) Patent Application Publication
(10) Pub. No.: US 2022/0404711 A1
(43) Pub. Date: Dec. 22, 2022

(54) PROCESS MONITORING AND TUNING USING PREDICTION MODELS

(71) Applicant: ASML NETHERLANDS B.V., Veldhoven (NL)

(72) Inventors: Ning GU, San Jose, CA (US); Liping REN, San Jose, CA (US); Kui-Jun HUANG, Shenzhen (CN); Jian WU, San Jose, CA (US)

(73) Assignee: ASML NETHERLANDS B.V., Veldhoven (NL)

(21) Appl. No.: 17/763,698

(22) PCT Filed: Sep. 22, 2020
(86) PCT No.: PCT/EP2020/076342

§ 371 Date: Mar. 25, 2022

Related U.S. Application Data
(60) Provisional application No. 62/909,668, filed on Oct. 2, 2019.

(51) Int. Cl. G03F 7/20; G05B 13/02

(52) U.S. Cl. CPC G03F 7/705; G03F 7/70633; G03F 7/70625; G05B 13/0265; H01L 21/682

(57) ABSTRACT

A method for monitoring performance of a manufacturing process is described. The method includes receiving one or more input signals that convey information related to geometry of a substrate generated by the manufacturing process; and determining, with a prediction model, variation in the manufacturing process based on the one or more input signals. A method for predicting substrate geometry associated with a manufacturing process is also described. The method includes receiving input information including geometry information and manufacturing process information for a substrate; and predicting, using a machine learning prediction model, output substrate geometry based on the input information. The method may further include tuning the predicted output substrate geometry. The tuning includes comparing the output substrate geometry to corresponding physical substrate measurements and/or predictions from a different non-machine learning prediction model, generating a loss function based on the comparison, and optimizing the loss function.

### CROSS-REFERENCE TO RELATED APPLICATIONS

This application claims priority of U.S. application 62/909,668 which was filed on Oct. 2, 2019 and which is incorporated herein in its entirety by reference.

### TECHNICAL FIELD

The description herein relates generally to systems and methods for manufacturing process monitoring and tuning using prediction models.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemical mechanical polishing, etc., all intended to finish an individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc. One or more metrology processes are typically involved in the patterning process.

Lithography is a step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

According to an embodiment, there is provided a method for monitoring performance of a manufacturing process. The method comprises receiving one or more input signals that convey information related to geometry of a substrate generated by the manufacturing process; and determining, with a prediction model, variation in the manufacturing process based on the one or more input signals.

In an embodiment, the substrate is associated with a semiconductor device, and the manufacturing process comprises a semiconductor device manufacturing process.

In an embodiment, the method further comprises determining an adjustment for a semiconductor device manufacturing apparatus based on the variation in the manufacturing process.

In an embodiment, the receiving and the determining are performed in real time or near real time during the semiconductor device manufacturing process.

In an embodiment, the one or more input signals comprise an overlay signal. In an embodiment, the one or more input signals comprise an alignment signal.

In an embodiment, the variation in the manufacturing process comprises one or more of variation in processing parameters of the manufacturing process, variation in material properties of one or more materials used in the manufacturing process, or variation in optical properties of the one or more materials.

In an embodiment, the prediction model comprises a machine learning model. In an embodiment, the prediction model comprises a neural network (as just one example), and/or other machine learning techniques.

In an embodiment, the substrate comprises a stack associated with a semiconductor device.

In an embodiment, the method further comprise training the prediction model based on known perturbations in the manufacturing process.

According to another embodiment, there is provided a method for predicting substrate geometry associated with a manufacturing process. The method comprises receiving input information including geometry information and manufacturing process information for a substrate; and predicting, using a machine learning prediction model, output substrate geometry based on the input information.

In an embodiment, the substrate comprises a stack associated with a semiconductor device.

In an embodiment, the method further comprises tuning the predicted output substrate geometry. The tuning comprises comparing the output substrate geometry to corresponding physical substrate measurements and/or predictions from a different non machine learning prediction model, generating a loss function based on the comparison, and optimizing the loss function.

In an embodiment, the tuning comprises stack tuning. Stack tuning inputs comprise (1) a signal associated with a measurement from a corresponding physical stack, (2) the geometry information, where the geometry information includes nominal geometry of the physical stack, and (3) the manufacturing process information. A stack tuning output comprises the output substrate geometry. The output substrate geometry is tuned such that a simulated signal determined based on the output substrate geometry corresponds to the signal associated with the measurement from the physical stack and/or the nominal geometry of the physical stack.

In an embodiment, the method further comprises predicting, with the machine learning prediction model, an overlay signal based on the output substrate geometry.

In an embodiment, the method further comprises predicting, with the machine learning prediction model, an alignment signal based on the output substrate geometry.

In an embodiment, the machine learning prediction model comprises a neural network.

In an embodiment, the geometry information comprises one or more dimensions of a target or mark design for one or more layers of a semiconductor device.

In an embodiment, the manufacturing process information comprises one or more parameters for one or more manufacturing processes performed on one or more layers of a semiconductor device.

In an embodiment, the method further comprises training the machine learning prediction model with training information that describes geometry, pattern, and manufacturing process parameters for training substrates, and corresponding physical substrate measurements and/or predictions from a different non machine learning prediction model.

According to another embodiment, there is provided a method for detecting variation in, and determining an adjustment for, one or more semiconductor device manufacturing process steps. The method comprises receiving input information including geometry information and manufacturing process information for a semiconductor device. The method comprises predicting, using a machine learning prediction model, output semiconductor device geometry variation based on the input information. The method comprises detecting variation in the semiconductor manufacturing process based on the semiconductor device geometry variation predictions from the machine learning prediction model. The method comprises determining one or more semiconductor device manufacturing process parameter variations based on the detected variation in the semiconductor device manufacturing process. The method comprises determining an adjustment for one or more of the semiconductor device manufacturing process steps based on the one or more determined semiconductor device manufacturing process parameter variations.

In an embodiment, the input information is for a stack associated with a semiconductor device.

In an embodiment, detecting variation in the semiconductor manufacturing process comprises predicting, with the machine learning prediction model, an overlay signal based on the output semiconductor device geometry variation. In an embodiment, detecting variation in the semiconductor manufacturing process comprises predicting, with the machine learning prediction model, an alignment signal based on the output semiconductor device geometry variation.

In an embodiment, the method further comprises tuning the predicted output semiconductor device geometry variation. The tuning comprises comparing the output semiconductor device geometry variation to corresponding physical measurements and/or predictions from a different non machine learning physical model, generating a loss function based on the comparison, and optimizing the loss function.

In an embodiment, the geometry information comprises one or more dimensions of a target design for one or more layers of a semiconductor device.

In an embodiment, the manufacturing process information comprises one or more etch process parameters, one or more deposition process parameters, and/or one or more chemical mechanical polishing process parameters.

In an embodiment, the adjustment for the semiconductor device manufacturing process comprises one or more of: a change in an etch process parameter from a first etch process parameter value to a second etch process parameter value; a change in a deposition process parameter from a first deposition process parameter value to a second deposition process parameter value; or a change in a chemical mechanical polishing process parameter from a first chemical mechanical polishing process parameter to a second chemical mechanical polishing process parameter value.

According to another embodiment, there is provided a computer program product comprising a non-transitory computer readable medium having instructions recorded thereon, the instructions when executed by a computer implementing any of the methods described above.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 schematically depicts a lithography apparatus, according to an embodiment.

FIG. 2 schematically depicts an embodiment of a lithographic cell or cluster, according to an embodiment.

FIG. 3A is a flow chart showing various stages of a design for control process flow, according to an embodiment.

FIG. 3B is a block diagram showing various stages for visualization, according to an embodiment.

FIG. 3C is a flow chart showing how the design for control process determines metrology target designs robust against process perturbations, according to an embodiment.

FIG. 4 illustrates operations of a method for monitoring performance of a manufacturing process, according to an embodiment.

FIG. 5 illustrates using geometry and process information (e.g., including purposeful variation of that information) as input to predict output signals indicative of predicted geometry (the reverse of the present method), according to an embodiment.

FIG. 6 illustrates an inverse (relative to the flow shown in FIG. 5) flow for the present system(s) and method(s), according to an embodiment.

FIG. 7A is a first illustration of receiving input signals and predicting and/or otherwise determining variation in a manufacturing process using a prediction model, according to an embodiment.

FIG. 7B is a second illustration of receiving input signals and predicting and/or otherwise determining variation in a manufacturing process using a prediction model, according to an embodiment.

FIG. 8 illustrates operations of a method for stack tuning using a machine learning prediction model, according to an embodiment.

FIG. 9 illustrates an example of a stack tuning flow, according to an embodiment.

FIG. 10 is a block diagram of an example computer system, according to an embodiment.

FIG. 11 is a schematic diagram of a lithographic projection apparatus similar to FIG. 1, according to an embodiment.

FIG. 12 is a more detailed view of the apparatus in FIG. 11, according to an embodiment.

FIG. 13 is a more detailed view of the source collector module SO of the apparatus of FIG. 11 and FIG. 12, according to an embodiment.

### DETAILED DESCRIPTION

The description herein relates generally to systems and methods for manufacturing process monitoring and tuning using prediction models. Manufacturing processes may include semiconductor manufacturing processes as described below. However, this example is not intended to be limiting. Operations the same as or similar to the ones described here may be applied in other manufacturing processes. Maintaining stable semiconductor manufacturing processes is important. Unexpected variations in manufacturing processes such as lithography, deposition, etching, chemical mechanical polishing (CMP) and/or other semiconductor manufacturing processes often have a negative impact on a final process yield. Detecting variation in real time or near real time (e.g., within seconds or minutes of the variation) allows timely adjustment of the manufacturing process to prevent production of defective devices, and increases the process yield. Thus, a simple, fast, and non-destructive solution capable of monitoring process variation, and providing information on which processes have varied, and by how much, during typical manufacturing, is desirable.

Prior systems have limitations that decrease their usefulness. For example, an ellipsometer can non-destructively measure a thin film thickness, but only one layer at a time. Consequently, the process of reconstructing a whole stack can take a very long time, sometimes up to several days or even weeks. Cross sectional inspection with a scanning electron microscope (SEM) can provide accurate process variation information, but this type of inspection is destructive and time consuming. Atomic force microscopy (AFM) can provide localized topology information with high accuracy, but AFM can only provide information about the top layer of a stack, and AFM is very slow. Prior modelling systems can indicate that a process has varied, but cannot provide detailed information about what process or process parameter has changed, or by how much. Sometimes, these modelling systems take several hours to days to generate output, which prevents them from being used for real time or near real time manufacturing process monitoring.

Advantageously, the present system(s) and method(s) provide for monitoring the performance of a (e.g., semiconductor) manufacturing process in real time or near real time. In the present system(s) and method(s), one or more input signals that convey information related to geometry of a substrate generated during the manufacturing process are received, and variation in the manufacturing process is determined using a prediction model (e.g., a machine learning model) based on the one or more input signals. The input signals may include overlay, alignment, and/or other signals, for example. The determined variation may provide quantitative process feedback that facilitates various manufacturing process adjustments.

The present system(s) and method(s) are configured to provide a real time or near real time response. The predicting process with the model is almost instantaneous, which makes the present system(s) and method(s) suitable for real time or near real time process monitoring. The predictions can also provide detailed information on which process has changed by how much. The present system(s) and methods are versatile. They can be used to monitor many different types of process variation. For example, they can be used to monitor thickness changes, material optical property changes (e.g., changes in n and/or k—the real and imaginary parts of a materials complex refractive index), side wall angle (SWA) changes, etch tilt angle changes, chemical mechanical polishing changes, etc. The present system(s) and method(s) are also configured to provide accurate indications of how much change has occurred for any of these types of process variation, and/or other types of process variation. Importantly, the present system(s) and method(s) can be used to monitor these and other types of variation in multiple layers of a stack (for example) simultaneously.

The present system(s) and method(s) are nondestructive and easy to apply. The present system(s) and method(s) are low cost to implement, do not (negatively) impact process yield, and are highly accurate. For example, the present system(s) and method(s) utilize overlay, alignment, and/or other signals comprising measurement data to predict process variation. Obtaining an overlay, alignment, or other signals that are already generated as part of a typical manufacturing process is convenient and inexpensive. Obtaining and utilizing the information in these signals to make predictions is not destructive to manufactured devices and does not require additional measurements (e.g., such that process yield is not negatively affected).

Turning to the tuning aspect of the present system(s) and method(s), stack tuning is a process that enhances agreement between overlay, alignment, and/or other measurement data with corresponding predictions from an electronic (e.g., D4C) model. Typical stack tuning iteratively progresses through a series of operations to generate an optimized stack. The iterations are guided by optimization algorithms such as gradient decent and trust region, to generate an optimized stack whose optical key performance indicator (KPI), for example, matches or nearly matches a KPI associated with the measurement data.

The iterative nature of typical stack tuning, along with the fact that predictions from the (non-machine learning) electronic model often take several hours or even several days, causes typical stack tuning to run very slowly. For example, it can take several days or weeks to finish a typical stack tuning process. The stack tuning process speed cannot be increased by simply adding more processing resources since (e.g., geometry) input for a subsequent iteration depends on the output from a previous iteration. Thus, in order to reduce the stack tuning time, it is necessary to shorten the running time for individual iterations.

Advantageously, the present system(s) and method(s) replace the typical time consuming predictions from the (non-machine learning) electronic and/or optical model, with faster predictions from an improved machine learning model. The present system(s) and method(s) utilize a trained machine learning prediction model configured to generate predictions almost instantly.

Although specific reference may be made in this text to the manufacture of integrated circuits (ICs), it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

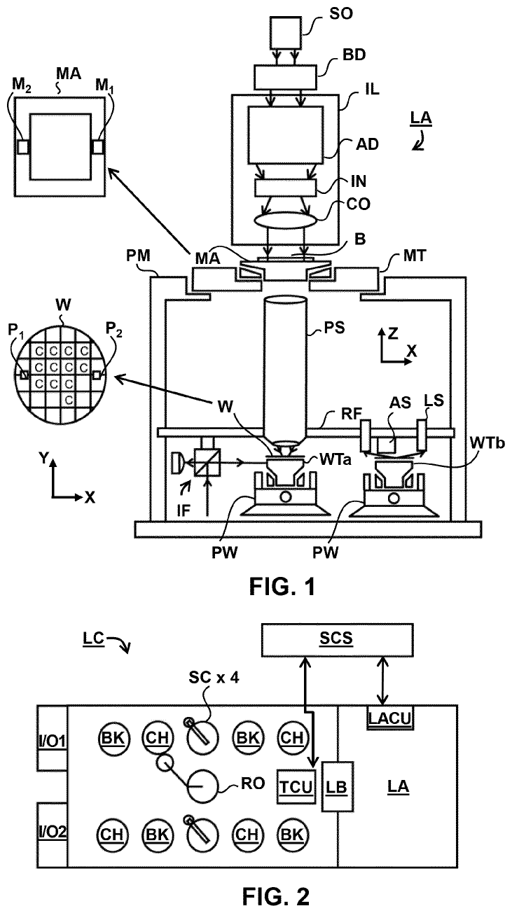

As an introduction, FIG. 1 schematically depicts an embodiment of a lithographic apparatus LA that may be included in and/or associated with the present systems and/or methods. The apparatus comprises:
an illumination system (illuminator) IL configured to condition a radiation beam B (e.g. UV radiation, DUV radiation, or EUV radiation);
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame (RF).

As depicted, the apparatus is of a transmissive type (e.g. employing a transmissive mask). Alternatively, the apparatus may be of a reflective type (e.g. employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The projection system PS has an optical transfer function which may be non-uniform, which can affect the pattern imaged on the substrate W. For unpolarized radiation such effects can be fairly well described by two scalar maps, which describe the transmission (apodization) and relative phase (aberration) of radiation exiting the projection system PS as a function of position in a pupil plane thereof. These scalar maps, which may be referred to as the transmission map and the relative phase map, may be expressed as a linear combination of a complete set of basis functions. A convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be determined by calculating the inner product of a measured scalar map with each Zernike polynomial in turn and dividing this by the square of the norm of that Zernike polynomial.

The transmission map and the relative phase map are field and system dependent. That is, in general, each projection system PS will have a different Zernike expansion for each field point (i.e. for each spatial location in its image plane). The relative phase of the projection system PS in its pupil plane may be determined by projecting radiation, for example from a point-like source in an object plane of the projection system PS (i.e. the plane of the patterning device MA), through the projection system PS and using a shearing interferometer to measure a wavefront (i.e. a locus of points with the same phase). A shearing interferometer is a common path interferometer and therefore, advantageously, no secondary reference beam is required to measure the wavefront. The shearing interferometer may comprise a diffraction grating, for example a two dimensional grid, in an image plane of the projection system (i.e. the substrate table WTa or WTb) and a detector arranged to detect an interference pattern in a plane that is conjugate to a pupil plane of the projection system PS. The interference pattern is related to the derivative of the phase of the radiation with respect to a coordinate in the pupil plane in the shearing direction. The detector may comprise an array of sensing elements such as, for example, charge coupled devices (CCDs).

The projection system PS of a lithography apparatus may not produce visible fringes and therefore the accuracy of the determination of the wavefront can be enhanced using phase stepping techniques such as, for example, moving the diffraction grating. Stepping may be performed in the plane of the diffraction grating and in a direction perpendicular to the scanning direction of the measurement. The stepping range may be one grating period, and at least three (uniformly distributed) phase steps may be used. Thus, for example, three scanning measurements may be performed in the y-direction, each scanning measurement being performed for a different position in the x-direction. This stepping of the diffraction grating effectively transforms phase variations into intensity variations, allowing phase information to be determined. The grating may be stepped in a direction perpendicular to the diffraction grating (z direction) to calibrate the detector.

The diffraction grating may be sequentially scanned in two perpendicular directions, which may coincide with axes of a co-ordinate system of the projection system PS (x and y) or may be at an angle such as 45 degrees to these axes. Scanning may be performed over an integer number of grating periods, for example one grating period. The scanning averages out phase variation in one direction, allowing phase variation in the other direction to be reconstructed. This allows the wavefront to be determined as a function of both directions.

The transmission (apodization) of the projection system PS in its pupil plane may be determined by projecting radiation, for example from a point-like source in an object plane of the projection system PS (i.e. the plane of the patterning device MA), through the projection system PS and measuring the intensity of radiation in a plane that is conjugate to a pupil plane of the projection system PS, using a detector. The same detector as is used to measure the wavefront to determine aberrations may be used.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes:

1. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns. These patterns can be referred to as “hot spots” or “process window limiting patterns (PWLPs),” which are used interchangeably herein. When controlling a part of a patterning process, it is possible and economical to focus on the hot spots. When the hot spots are not defective, it is most likely that other patterns are not defective.

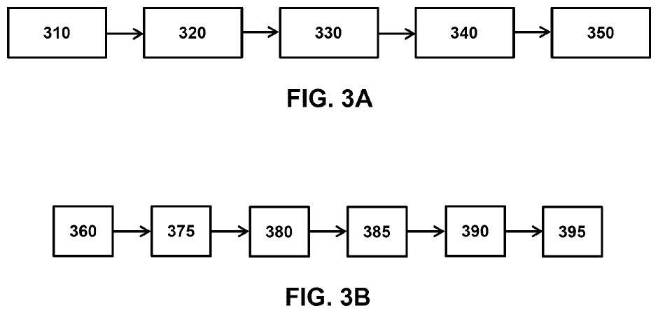

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating). This can be done as described above and as described, for example, in U.S. patent application publication US 2006-066855, which is incorporated herein in its entirety by reference. Another application of diffraction-based metrology is in the measurement of feature width (CD) within a target.

Thus, in a device fabrication process (e.g., a patterning process, a lithography process, etc.), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

Within a metrology system MET, a metrology apparatus is used to determine one or more properties of the substrate, and in particular, how one or more properties of different substrates vary, or different layers of the same substrate vary from layer to layer. As noted above, the metrology apparatus may be integrated into the lithographic apparatus LA or the lithocell LC or may be a stand-alone device.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

In an embodiment, one of the parameters of interest of a patterning process is overlay. Overlay can be measured using dark field scatterometry in which the zeroth order of diffraction (corresponding to a specular reflection) is blocked, and only higher orders processed. Examples of dark field metrology can be found in PCT patent application publication nos. WO 2009/078708 and WO 2009/106279, which are hereby incorporated in their entirety by reference. Further developments of the technique have been described in U.S. patent application publications US2011-0027704, US2011-0043791 and US2012-0242970, which are hereby incorporated in their entirety by reference. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

As lithography nodes keep shrinking, more and more complicated wafer designs may be implemented. Various tools and/or techniques may be used by designers to ensure complex designs are accurately transferred to physical wafers. These tools and techniques may include mask optimization, source mask optimization (SMO), OPC, design for control, and/or other tools and/or techniques. For example, a source mask optimization process is described in U.S. Pat. No. 9,588,438 titled “Optimization Flows of Source, Mask and Projection Optics”, which is incorporated in its entirety by reference.

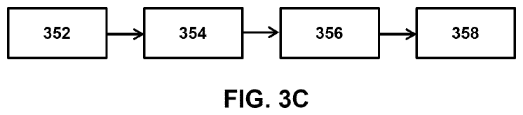

FIG. 3A shows a flowchart that lists the main stages of a “design for control” (D4C) method. In stage 310, the materials to be used in the lithography process are selected. The materials may be selected from a materials library interfaced with D4C through an appropriate GUI. In stage 320, a lithography process is defined by entering each of the process steps, and building a computer simulation model for the entire process sequence.

For example, the simulation can be used to configure one or more features of the patterning device pattern (e.g., performing optical proximity correction), one or more features of the illumination (e.g., changing one or more characteristics of a spatial/angular intensity distribution of the illumination, such as change a shape), one or more features of the projection optics (e.g., numerical aperture, etc.), one or more features of individual lithography operations such as etching, deposition, CMP, etc., and/or other aspects of a process sequence. In some embodiments, the simulation may comprise separate models for the individual aspects of the process sequence (e.g., etch, deposition, CMP, etc.), where output from a prior process step model is used as input for a subsequent process step model.

In some embodiments, a model may be used to optimize a (step (operation) in a) wafer manufacturing process. An optimization process of a manufacturing process may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on an image on a substrate, as well as non-physical characteristics.

In some embodiments, a given model associated with and/or included in an integrated circuit manufacturing process may be an empirical model that models the operations of a corresponding processing method. The empirical model may predict outputs based on correlations between various inputs (e.g., one or more characteristics of a mask or wafer image, one or more characteristics of a design layout, one or more characteristics of the patterning device, one or more characteristics of the lithographic process (e.g., etching, deposition, CMP, etc.).

As an example, an empirical model may be a machine learning model and/or any other parameterized model. In some embodiments, the machine learning model (for example) may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

As an example, the one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be freer flowing, with connections interacting in a more chaotic and complex fashion. In some embodiments, the intermediate layers of the one or more neural networks include one or more convolutional layers, one or more recurrent layers, and/or other layers.

The one or more neural networks may be trained (i.e., whose parameters are determined) using a set of training data. The training data may include a set of training samples. Each sample may be a pair comprising an input object (typically a vector, which may be called a feature vector) and a desired output value (also called the supervisory signal). A training algorithm analyzes the training data and adjusts the behavior of the neural network by adjusting the parameters (e.g., weights of one or more layers) of the neural network based on the training data. For example, given a set of N training samples of the form {(x₁, y₁), (x₂, y₂), . . . , (x_{N}, y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object (e.g., a wafer design as in the example above, a clip, etc.). The vector space associated with these vectors is often called the feature space. After training, the neural network may be used for making predictions using new samples. In some embodiments, the one or more neural networks may include convolutional neural networks (CNN), deep neural networks (DNN), and/or other types of neural networks. In some embodiments, the one or more neural networks may include and/or work together with various types of artificial intelligence (AI).

In stage 330, a metrology target is defined, i.e. dimensions and other characteristics of various features included in the target are entered into the D4C program. For example, if a grating is included in a structure, then number of grating elements, width of individual grating elements, spacing between two grating elements etc. have to be defined. In stage 340, the 3D geometry is created. This step also considers whether there is any information relevant to a multi-layer target design, for example, the relative shifts between different layers. This feature enables multi-layer target design. In stage 350, the final geometry of the designed target is visualized. As will be explained in greater detail below, not only the final design is visualized, but as the designer applies various steps of the lithography process, he/she can visualize how the 3D geometry is being formed and changed because of process-induced effects. For example, the 3D geometry after resist patterning is different from the 3D geometry after resist removal and etching.

Different visualization tools, referred to as “viewers,” are built into the D4C software. For example, as shown in FIG. 3B, a designer can view material plots 360 (and may also get a run time estimation plot) depending on the defined lithography process and target. Once the lithography model is created, the designer can view the model parameters through model viewer tool 375. Design layout viewer tool 380 may be used to view the design layout (e.g., visual rendering of the GDS file). Resist profile viewer tool 385 may be used to view pattern profiles in a resist. Geometry viewer tool 390 may be used to view 3D structures on a substrate. A pupil viewer tool 395 may be used to view simulated response on a metrology tool. Persons skilled in the art would understand that these viewing tools are available to enhance the understanding of the designer during design and simulation. One or more of these tools may not be present in some embodiments of D4C software, and additional viewing tools may be there in some other embodiments.

FIG. 3C shows a flow chart that illustrates how the D4C process increases efficiency in the overall simulation process by reducing the number of metrology targets selected for the actual simulation of the lithography process. As mentioned before, D4C enables designers to design thousands or even millions of designs. Not all of these designs may be robust against variations in the process steps. To select a subset of target designs that can withstand process variation, a lithographer may intentionally perturb one or more steps of the defined lithography process, as shown in block 352. The introduction of the perturbation alters the entire process sequence with respect to how it was originally defined. Therefore, applying the perturbed process sequence (block 354) alters the 3D geometry of the designed target too. A lithographer only selects the perturbations that show nonzero alternations in the original design targets and creates a subset of selected process perturbations (block 356). The lithography process is then simulated with this subset of process perturbations (block 358).

The manufacturing or fabrication of a substrate using the lithographic process (or patterning process in general) typically involves process variations. The process variations are not uniform across the substrate. For example, in deposition processes, films tend to be thicker at the center of the substrate and be thinner when close to an edge. These systematic variations are usually reflected in measurement data as ‘fingerprints’, which are characteristics of a substrate based on known process conditions. In other words, there exists a stack on a substrate that has a spatial variation as a function of substrate coordinate. A stack comprises multiple layers formed on a substrate during the patterning process to form a selected pattern (e.g., a design pattern) on the substrate. Each layer of the stack can be associated with a thickness, material properties, and features and related parameters of the patterning process (e.g. CD, pitch, overlay, etc.).

The present systems, and/or methods may be used as stand-alone tools and/or techniques, used in conjunction with a D4C process, and/or or used in conjunction with other semiconductor manufacturing processes where process modeling is used, to enhance the accurate transfer of complex designs to physical wafers.

As described above, maintaining stable semiconductor manufacturing processes is important. The present system(s) and method(s) provide for monitoring the performance of a (e.g., semiconductor) manufacturing process in real time or near real time. In the present system(s) and method(s), one or more input signals that convey information related to geometry of a substrate generated during the manufacturing process are received, and variation in the manufacturing process is determined using a prediction model (e.g., a machine learning model) based on the one or more input signals and/or other information. The predicted variation may include predictions related to geometry of features in a substrate, predictions related to specific manufacturing processes (e.g., deposition, etching, chemical mechanical polishing, etc.), predictions related to individual parameters of one or more of those manufacturing processes (e.g., as described below), and/or other information. The input signals may include overlay, alignment, and/or other signals, for example. The determined variation may provide quantitative process feedback that facilitates various manufacturing process adjustments.

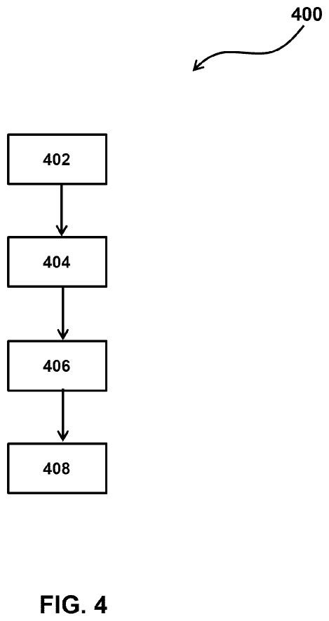

By way of a non-limiting example, FIG. 4 illustrates operations of a method 400 for monitoring performance of a manufacturing process. In some embodiments, method 400 comprises training 402 a prediction model, receiving 404 one or more input signals, determining 406, with the prediction model, variation in a manufacturing process based on the one or more input signals, and adjusting 408 a manufacturing process and/or manufacturing apparatus based on the determined variation in the manufacturing process. In some embodiments, the substrate is associated with a semiconductor device, and the manufacturing process comprises a semiconductor device manufacturing process. In some embodiments, the substrate comprises a stack associated with a semiconductor device, and/or other substrates, for example. The operations of method 400 are intended to be illustrative. In some embodiments, method 400 may be accomplished with one or more additional operations not described, and/or without one or more of the operations discussed. For example, operation 408, and/or other operations, may be optional. Additionally, the order in which the operations of method 400 are illustrated in FIG. 4 and described below is not intended to be limiting.

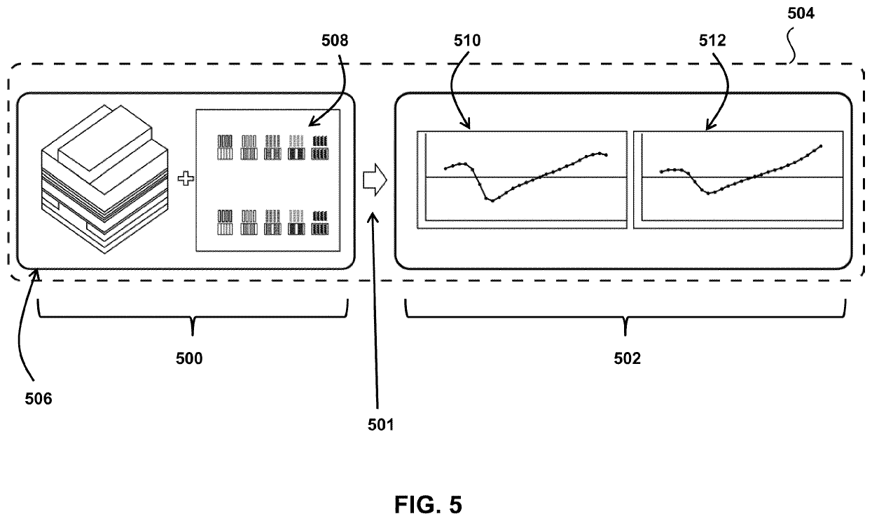

Method 400 shown in FIG. 4, where input (e.g., alignment, overlay, etc.) signals are used to predict process variation, contrasts with typical methods, which function in reverse, using geometry and process information (e.g., including purposeful variation of that information) as input to predict output signals (e.g., overlay, alignment, etc.) indicative of predicted geometry. An example of a typical method is illustrated in FIG. 5. FIG. 5 illustrates using geometry and process information 500 as input to predict 501 output signals 502 indicative of predicted geometry (the reverse of the present method). FIG. 5 illustrates a typical (e.g., D4C) simulation flow 504. For given input geometry and process information such as a stack 506, corresponding process parameters (not listed in FIG. 5), and/or a target pattern definition 508, output signals 502 comprising, for example, different KPI swing curves 510, 512 (e.g., SS, DE, etc.,) can be simulated (with a typical D4C model). A swing curve is a curve that describes the wavelength dependence of a KPI, for example SS. With this curve, one can determine which wavelength is optimal for an overlay and alignment measurement. SS stands for stack sensitivity. DE stands for diffraction efficiency. A swing curve shows variation in a given process parameter, for example. Mathematically, flow 504 can be expressed as:

f(t₁,t₂, . . . , tₙ)=SS(λ₁,λ₂, . . . , λₘ)

where the f denotes the simulation engine or simulation function, t_{1,2, . . . n} are example geometry information inputs—thicknesses of each layer (e.g., of a stack) in this example), and λ_{1,2, . . . , n} are the wavelengths at which KPIs (for example) are calculated (predicted). In this example equation, input parameter variation is limited to thickness variations only, but the input parameter variation can also include variation related to n and/or k change, SWA change, tilting angle change, and other process parameter variation. Continuing with this example, if the equation above is rewritten in vector form, using the thickness of each layer as an input vector and a corresponding KPI swing curve as an output vector, then then (e.g., D4C) flow 504 can be described as:

(t₁,t₂, . . . ,tₙ)⇒D4C⇒(SS_{λ1},SS_{λ2}, . . . ,SS_{λm}).

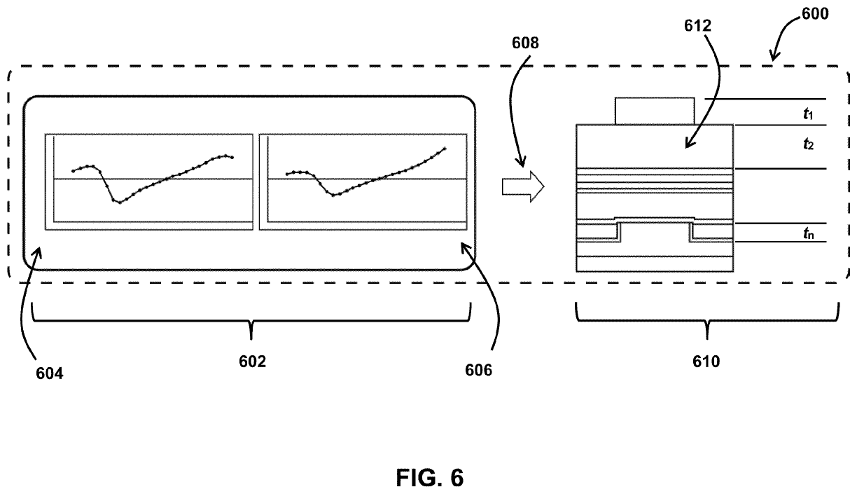

Conversely, the present system(s) and method(s) can be thought of as functioning with an inverse flow relative to the flow of flow 504. For example, FIG. 6 illustrates an inverse (relative to flow 504) flow 600 for the present system(s) and method(s). Flow 600 includes receiving 602 one or more input signals 604, 606 (measured SS curves in this example), and predicting and/or otherwise determining 608, with a prediction model, variation 610 in a manufacturing process based on the one or more input signals 604, 606. The predicted variation may include predictions related to geometry of features in a substrate, predictions related to specific manufacturing processes (e.g., deposition, etching, chemical mechanical polishing, etc.), predictions related to individual parameters of one or more of those manufacturing processes, and/or other information. In this example, input signals 604, 606 convey (e.g., physically measured) information related to geometry of a substrate (e.g., a stack and/or other substrates) generated by a manufacturing process, and/or other information. Predicted variation 610 can include information such as stack geometry including thicknesses of various layers (e.g., t₁, t₂, . . . , tₙ), corresponding variation in process parameters such as n and/or k change, SWA change, tilting angle change, and other process parameter variation (not listed in FIG. 6), and/or other information, for example.

Similar to flow 504 shown in FIG. 5, (e.g., inverse D4C) flow 600 can also be expressed as a vector in the form:

(SS_{λ1},SS_{λ2},SS_{λm})⇒D4C⁻¹⇒(t₁,t₂, . . . , tₙ)

This inversved relation comprises a complicated nonlinear mapping in a high dimensional space, and is difficult to solve analytically or using a numerical simulation. However, since both the inputs and outputs are vectors with fixed lengths, and the swing curves (for example) and/or other measured information may be used to encode rich information describing process variation, this problem is suitable for solving with machine learning algorithms, neural netorks, and/or other prediction models.

Returning to FIG. 4, and as described above, at an operation 402, a prediction model is trained. In some embodiments, the prediction model comprises a machine learning model. In some embodiments, the prediction model and/or the machine learning model comprises one or more neural networks. Machine learning usually requires large amounts of information to train a model. Fortunately here, this training information can be obtained from prior or existing (e.g., D4C) simulations based on large numbers of random (but known) perturbations for a nominal stack.

The prediction model is trained with training information. The training information may include pairs or sets of input objects and corresponding measured or desired output values. The training information may comprise one or more of an electronic signal associated with substrate geometry, images, target patterns, patterning process parameters, and/or other information, and corresponding physical substrate measurements, known process parameters and/or process parameter variations, and/or other information. By way of a non-limiting example, the prediction model is trained based on known perturbations in the manufacturing process. The known process perturbations may be caused by purposely varying one or more manufacturing process parameters (variables) in a known way, making physical measurements on a resulting substrate, and/or other activities. The resulting substrate may be used to measure an electronic signal (e.g., an overlay signal, an alignment signal, etc.) that is representative of the resulting substrate produced with the known process perturbations. The known perturbations and the corresponding electronic signals may be paired. The pairs may be provided to the prediction model as training information. The prediction model may self-learn (e.g., when the model is or includes a neural network) using the provided pairs of training information. A trained prediction model may be used to make new predictions (e.g., predict new process perturbations) based on different input information such as different electronic signals and/or other information.

At an operation 404 one or more input signals are received. The input signals may be, and/or be included in, the different input information described above with respect to training. The input signals convey information related to geometry of a substrate generated by the manufacturing process and/or other information. In some embodiments, the input signals comprise an overlay signal. In some embodiments, the one or more input signals comprise an alignment signal. For example, as described above, the one or more input signals may comprise measured SS, DE, K, and/or other signals. These example signals are not intended to be limiting.

At an operation 406, variation in a manufacturing process is predicted and/or otherwise determined using the prediction model. The variation is predicted and/or otherwise determined based on the one or more input signals and/or other information. The predicted and/or otherwise determined variation may include predictions and/or determinations related to geometry of features in a substrate (e.g., thicknesses of layers in a stack), predictions and/or determinations related to specific manufacturing processes (e.g., deposition, etching, chemical mechanical polishing, etc.), predictions and/or determinations related to individual parameters of one or more of those manufacturing processes, and/or other information. In some embodiments, the variation in the manufacturing process comprises one or more of variation in processing parameters of the manufacturing process, variation in material properties of one or more materials used in the manufacturing process, variation in optical properties of the one or more materials, and/or other variation. In some embodiments, processing parameters of a manufacturing process may include etch depth, deposition parameters, side wall angle, etch floor tilt, etch bias, lithography CD bias, and/or other parameters. In some embodiments, material and/or optical properties of the one or more materials used in the manufacturing process may include optical properties such as n or k of the reflection index change at different wavelengths, and/or other properties.

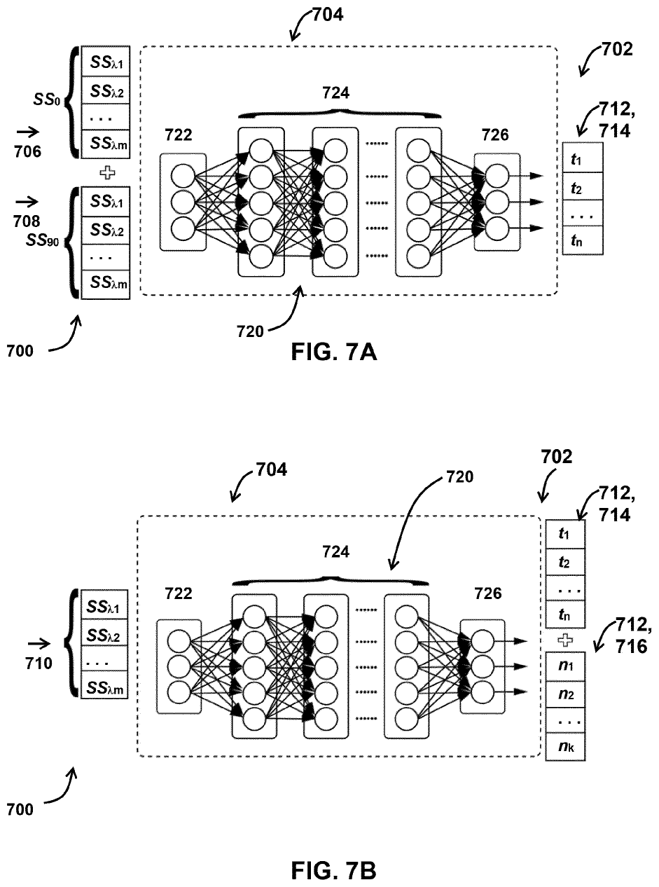

By way of a non-limiting example, FIGS. 7A and 7B illustrate receiving input signals 700 and predicting and/or otherwise determining 702 variation in a manufacturing process using a prediction model 704. In FIGS. 7A and 7B, input signals 700 comprise SS KPI swing curves for different wavelengths λ_{1,2, . . . m}. FIG. 7A shows two separate sets of SS signals 706, 708, while FIG. 7B shows a summary combined set of SS signals 710. FIG. 7A illustrates output 712 from model 704 comprising material property information 714 such as stack layer thicknesses t₁, t₂, . . . , tₙ. FIG. 7B illustrates output 712 from model 704 comprising material property information 714 such as stack layer thicknesses t₁, t₂, . . . , tₙ, and optical property information 716 such as n₁, n₂, . . . , nₖ. These examples are not intended to be limiting. FIG. 7B illustrates the versatility of the present system(s) and method(s). By slightly modify the output 712, the same model 704 can be used to predict not only the thickness changes (e.g., 714) but n and/or k (e.g., 716) changes as well. Using similar techniques, asymmetric process variation evidenced by tilt angle and side wall angle, and/or other process variation can also be predicted. These examples are not intended to be limiting.

FIGS. 7A and 7B illustrate how prediction model 704 may be and/or include a neural network 720 (having an input layer 722, hidden layers 724, and an output layer 726) configured to predict and/or otherwise determine the thickness of each layer from based on swing curves for stack sensitivity measurements. It should be noted that although neural network 720 is suitable to solve this kind of problem, model 704 is not limited only to neural networks. Although FIGS. 7A and 7B illustrate neural networks as an example of a machine learning mechanism, the present disclosure is not intended to be limited only to neural networks. Any other machine learning technique can be applied if it produces acceptable results.

It should be noted that even though FIGS. 7A and 7B illustrate predicting and/or otherwise determining individual values for individual parameters, prediction model 704 may be configured (e.g., trained) to predict and/or otherwise determine corresponding variation in these parameters (e.g., over time, from a target or set value, relative to each other, etc.), predict and/or otherwise determine a manufacturing process that these parameters are associated with, and/or determine other variation in a manufacturing process. In some embodiments, process variation may be determined based on individual values predicted and/or determined for individual parameters. For example, one or more mathematical operations can be used, in combination with multiple predictions of the same parameter over time, to determine that a parameter changes over time, and/or by how much.

Returning to FIG. 4, at an operation 408, a manufacturing process and/or manufacturing apparatus is adjusted based on the determined variation in the manufacturing process. In some embodiments, operation 408 includes determining an adjustment for the manufacturing process and/or manufacturing apparatus (e.g., a parameter to adjust, an apparatus to adjust, an amount to adjust the parameter, an amount to adjust the apparatus, etc.), and then adjusting the manufacturing process and/or manufacturing apparatus based on the determined adjustment. In some embodiments, the receiving (operation 404), the determining (operation 406), the adjusting (operation 408), and/or other operations are performed in real time or near real time during the manufacturing process. In some embodiments, in real time or near real time may be and/or include a time that occurs within seconds or minutes of the variation, and allows timely adjustment of the manufacturing process to prevent production of defective devices, and increase the process yield.

In some embodiments, adjustments may be based on which predictions and/or determinations of which manufacturing process has varied and by how much. In addition, adjustments may be made based on predictions and/or determinations for a full stack (and/or other substrates) with multiple kinds of process variation. For example, adjustments may be based on predicted and/or otherwise determined thickness changes, SWA changes, tilt angle changes, and/or other changes for multiple layers of a stack, n and/or k changes for multiple materials in a stack, etc.) simultaneously.

Turning to the tuning aspect of the present system(s) and method(s), as described above, stack tuning is a process that enhances agreement between overlay, alignment, and/or other measurement data with corresponding predictions from an electronic (e.g., non-machine learning D4C) model. Typical stack tuning iteratively progresses through a series of operations to generate an optimized stack. The iterative nature of typical stack tuning, along with the fact that predictions from the (non-machine learning) electronic model often take several hours or even several days, causes typical stack tuning to run very slowly. Advantageously, the present system(s) and method(s) replace the typical time consuming predictions from the (non-machine learning) physical model, with faster predictions from an improved machine learning model. The present system(s) and method(s) utilize a trained machine learning prediction model configured to generate predictions almost instantly.

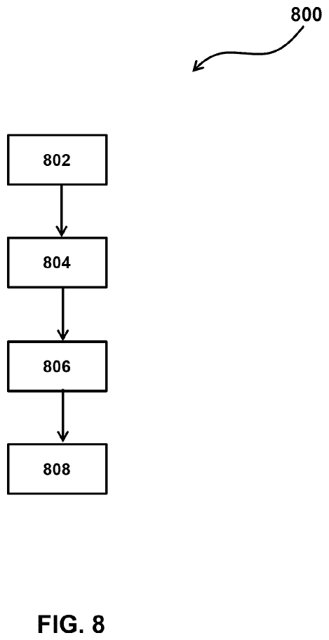

FIG. 8 illustrates operations of a method 800 for stack tuning using a machine learning prediction model. In some embodiments, method 800 comprises training 802 a machine learning prediction model, receiving 804 input information, predicting 806, with the machine learning prediction model, output substrate geometry based on the input information, and tuning 808 the predicted output substrate geometry (e.g., tuning the model). In some embodiments, the substrate comprises a stack associated with a semiconductor device, for example. The operations of method 800 are intended to be illustrative. In some embodiments, method 800 may be accomplished with one or more additional operations not described, and/or without one or more of the operations discussed. Additionally, the order in which the operations of method 800 are illustrated in FIG. 8 and described below is not intended to be limiting.

As described above, at operation 802, the machine learning prediction model is trained. In some embodiments, the machine learning model is or includes a neural network. The machine learning prediction model comprises training information. In some embodiments, operation 802 comprises training the machine learning prediction model with training information that describes geometry, pattern, and manufacturing process parameters for training substrates, and corresponding physical substrate measurements and/or predictions from a different non machine learning prediction model (e.g., a prior D4C model). The training information may include pairs or sets of input objects and corresponding measured or desired output values. The pairs may be provided to the machine learning prediction model as training information. The machine learning prediction model may self-learn (e.g., when the model is or includes a neural network) using the provided pairs of training information. A trained machine learning prediction model may be used to make new predictions based on different input information such as a different stack, different process parameters, and/or other information.

At an operation 804 input information is received. The input information includes geometry information and manufacturing process information for a substrate (e.g., a stack and/or other substrates), and/or other information. In some embodiments, the input information is for the stack associated with the semiconductor device and/or other substrates. In some embodiments, the geometry information comprises one or more dimensions (e.g., distances from one feature to another; thicknesses of layers; lengths, widths, diameters, etc. of various features; etc.) of a target or mark design for one or more portions of a semiconductor device; initial guesses and/or other determinations related to layer thicknesses; prior simulated KPI's; distances, angles, and/or other information that indicates a spatial orientation of one or more features of a pattern relative to each other (e.g., in “x”, “y”, and/or “z” directions); a .GDS file; the relative positions of design targets from different layers and the induced overlay; and/or other geometry information, for example.

The manufacturing process information comprises one or more parameters for one or more manufacturing processes performed on a substrate associated with a semiconductor device, and/or other information. For example, the manufacturing process information may include one or more etch process parameters, one or more deposition process parameters, one or more chemical mechanical polishing process parameters, and/or other process parameters. Examples of etch parameters, deposition parameters, and CMP parameters may include etch rate (e.g., vertical and/or horizontal), deposition rate, CMP pressure, velocity, etc., and/or other parameters. Process parameters may include values for process settings, values for maximum and/or minimum process window parameter set points, etchable materials, etch depth, etch SWA, CMP dishing, depth, etc., and/or any other information used to define and/or regulate a manufacturing process.

At an operation 806, output substrate geometry is predicted with the machine learning prediction model. In some embodiments, output substrate geometry variation (e.g., from target geometry, from previous geometry, and/or other geometry) is predicted. In some embodiments, electronic signals (e.g., overlay, alignment, etc.) may be predicted based on the output substrate geometry, the geometry variation, and/or other information. The output substrate geometry, geometry variation, and/or electronic signals are predicted based on the input information and/or other information. In some embodiments, operation 806 includes predicting, with the machine learning prediction model, an overlay signal, an alignment signal, and/or other information based on the output substrate geometry. In some embodiments, the overlay signal, the alignment signal, and/or other information may be predicted based on the output semiconductor device geometry, the geometry variation, and/or other information. In some embodiments, operation 806 includes detecting variation in the semiconductor manufacturing process based on the semiconductor device geometry, geometry variation, the overlay signal, the alignment signal, and/or other predictions from the machine learning prediction model.

At an operation 808, the predicted output substrate geometry, an electronic (e.g., overlay, alignment, etc.) signal, and/or other information predicted by the machine learning prediction model is tuned. This may be thought of as tuning the machine learning prediction model itself. In embodiments where the substrate comprises a stack, this may be thought of as stack tuning, for example. In some embodiments, operation 808 includes one or both of operations 806 and 804. In some embodiments, the tuning comprises comparing the output substrate geometry to corresponding physical substrate measurements and/or predictions from a different non machine learning prediction model, generating a loss function based on the comparison, optimizing the loss function, and/or other operations. In some embodiments, operation 808 includes receiving stack tuning inputs and outputting the substrate geometry. For example, in some embodiments, stack tuning inputs comprise a signal associated with a measurement from a corresponding physical stack, the geometry information, the manufacturing process information, and/or other information. The geometry information may include nominal geometry of the physical stack and/or other information. The output substrate geometry is tuned such that a simulated signal (e.g., overlay, alignment, etc.) determined based on the tuned output substrate geometry corresponds to the signal associated with the measurement from the physical stack and/or the nominal geometry of the physical stack.

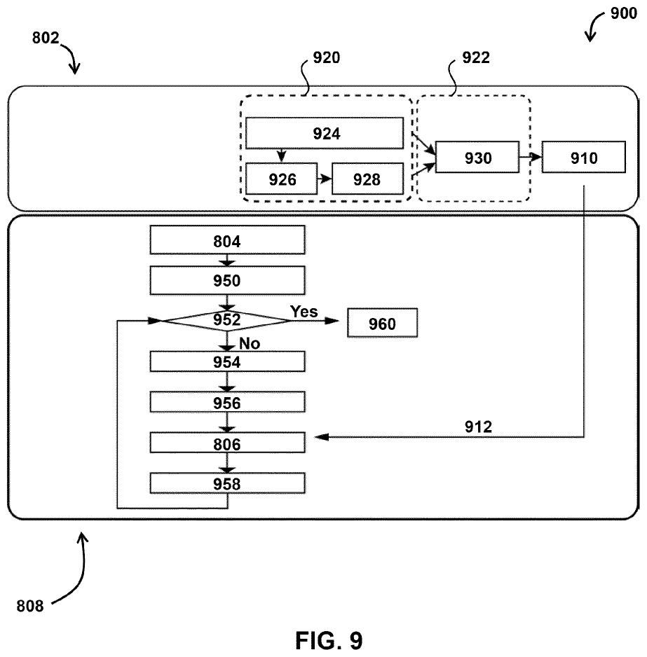

FIG. 9 illustrates an example of a new stack tuning flow 900. Stack tuning flow 900 includes training operation 802, tuning operation 808, input operation 804, predicting operation 806, and other operations. As shown in FIG. 9, two operations of tuning flow 900 comprise training operation 802 and tuning operation 808. In training operation 802, a machine learning prediction model (e.g., comprising a neural network and/or other algorithms) is trained. In tuning operation 808, the trained prediction model 910 is used to replace 912 a traditional non-machine learning model in order to greatly reduced the total required to complete tuning operation 808. Existing stack tuning flows may include the lower part of FIG. 9 from 804 to 956, including operation 960. As shown and described, in the new flow 900, what was operation 806 is replaced by the machine learning model described in the upper part 802 of FIG. 9.

As shown in FIG. 9, training operation 802 includes generating training information 920 and then actually training 922 the machine learning prediction model. In some embodiments, generating the training information 920 may include generating a large number of random process parameter variations 924, performing corresponding simulations with a non-machine learning model 926, and outputting predicted signals indicative of substrate geometry 928. In some embodiments, actually training 922 the machine learning prediction model may include training 930 one or more machine learning algorithms such a neural network and/or other algorithms. The random process parameter variations 924 and the predicted signals indicative of substrate geometry 928 may be used as training information for training 930.

In some embodiments, tuning operation 808 includes operation 804 (e g, making initial guesses related to process parameters, and performing simulations to generate initial signals such as KPI's), making 950 initial correlations of predictions with actual measurements, deciding 952 whether a correlation is good (or good enough), and assuming the correlations are not good (or not good enough), generating 954 a loss function, optimizing 956 the loss function, predicting (via operation 806) new substrate (e.g., stack) geometry (e.g., and/or electronic signals indicative of the substrate (stack) geometry) with the trained machine learning prediction model, and correlating 958 the newly predicted substrate (stack) geometry with the actual measurements. Steps 952958 may be iteratively repeated until acceptable correlation is achieved 960. Acceptable correlation may comprise correlation that satisfies correlation criteria, for example.

In some embodiments, the loss function is configured to determine how well the prediction model models a dataset. If the prediction model does not accurately model a dataset, the loss function is configured to output an indication of the inaccuracy. As the model is iteratively tuned, the output from the loss function indicates a more and more accurate model. The loss function is optimized with optimization algorithms. Some of the most commonly used optimization algorithms may include local optimization algorithms such as: Newton's method, Gradient Descent, Trust region, BFGS, etc., and/or global optimization algorithms such as: the annealing method, genetic algorithm, etc

Advantageously, as shown in FIG. 9, tuning operation 808 replaces the time consuming non-machine learning model simulation in each iteration of traditional tuning, with a machine learning based prediction model to reduce the total stack tuning time. Tuning operation 808 is able make full use of available computational resources during training operation 802, and thus can easily scale up tuning speed with increased processing power. Stack tuning iteration takes only several seconds or less using the stack tuning described in FIG. 9. Multi-iteration tuning processes can be completed in a relatively short amount of time. This makes the stack tuning described herein suitable for real time or near real time process monitoring. In comparison, prior stack tuning times increased linearly with the number of iterations (and can take hours or longer to complete). Further, the trained machine learning model of the present system(s) and method(s) can make predictions for inputs not within the training information.

Returning to FIG. 8, in some embodiments, operation 808 includes determining one or more semiconductor device manufacturing process parameter variations. Operation 808 may include determining whether the process parameter variations are inside a tolerance window, outside a tolerance window, and/or have other variations, for example. The process parameter variations may be determined based on the semiconductor device geometry, geometry variation, the overlay signal, the alignment signal, the tuned stack, and/or other information. In some embodiments, operation 808 includes determining an adjustment for, and/or adjusting, one or more of the semiconductor device manufacturing process steps based on the one or more determined semiconductor device manufacturing process parameter variations and/or other information. For example, operation 808 may include adjusting a mask design, geometry of a pattern feature, a dose, a focus, etch parameters, deposition parameters, and/or other parameters for the semiconductor device manufacturing process. These adjustment may be made based on the determined process parameter variations.

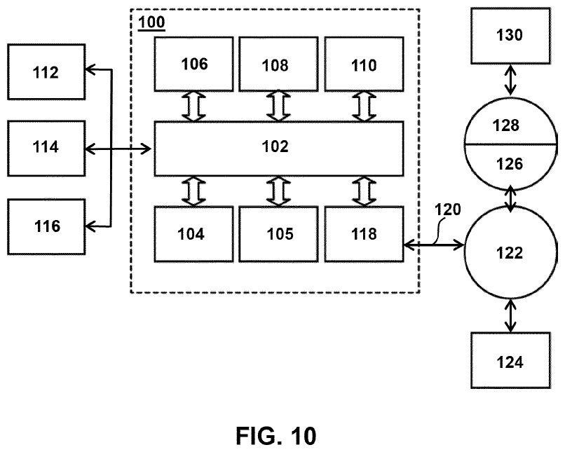

FIG. 10 is a block diagram that illustrates a computer system 100 that can assist in implementing the methods, flows or the system(s) disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide all or part of a method described herein, for example. The received code may be executed by processor 104 as it is received, and/or stored in storage device 110, or other non-volatile storage for later execution. In this manner, computer system 100 may obtain application code in the form of a carrier wave.

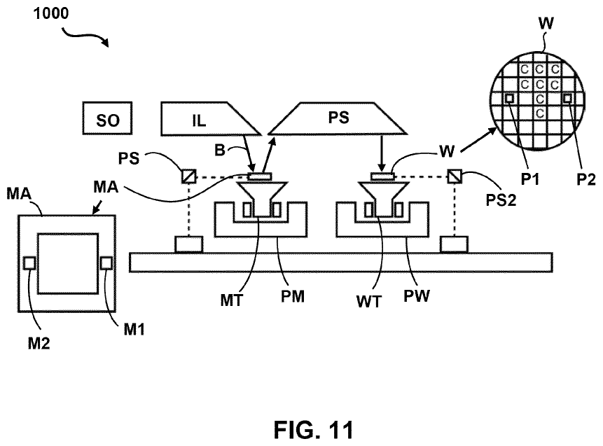

FIG. 11 schematically depicts an exemplary lithographic projection apparatus 1000 similar to and/or the same as the apparatus shown in FIG. 1 that can be used in conjunction with the techniques described herein. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means for setting the outer and/or inner radial extent (commonly referred to as σ-outer and σ-inner, respectively) of the intensity distribution in the beam. In addition, it will generally comprise various other components, such as an integrator and a condenser. In this way, the beam B impinging on the patterning device MA has a desired uniformity and intensity distribution in its cross-section.

It should be noted with regard to FIG. 11 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means), the substrate table WT can be moved accurately, e.g. to position different target portions C in the path of the beam. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one operation (i.e., a single “flash”) onto a target portion C. The substrate table WT is then shifted in the x and/or y directions so that a different target portion C can be irradiated by the beam;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

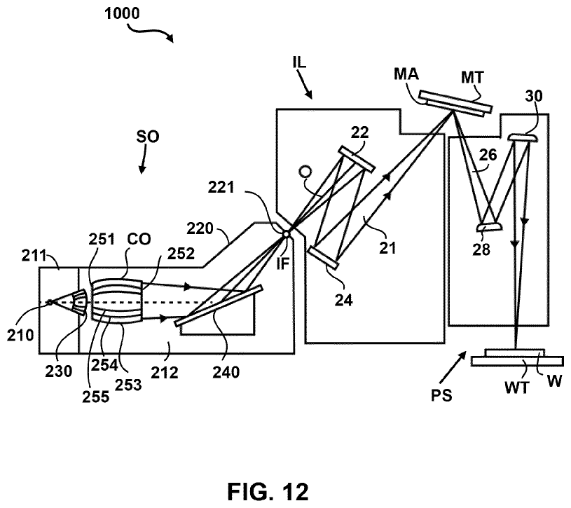

FIG. 12 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the line O. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 11.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

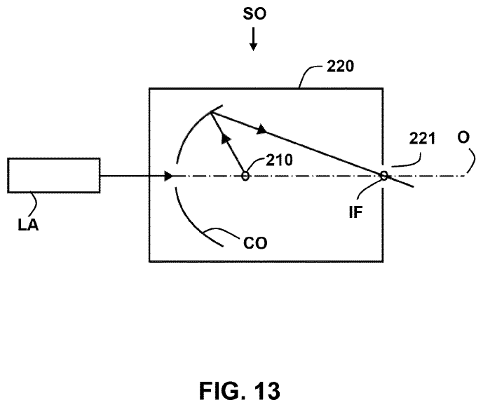

Alternatively, the source collector module SO may be part of an LPP radiation system as shown in FIG. 13. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

Embodiments of the present disclosure can be further described by the following clauses.

1. A method for detecting variation in, and determining an adjustment for, a semiconductor device manufacturing process, the method comprising:

receiving input information including geometry information and manufacturing process information for a semiconductor device;

predicting, using a machine learning prediction model, output semiconductor device geometry variation based on the input information;

detecting variation in the semiconductor manufacturing process based on the semiconductor device geometry variation predictions from the machine learning prediction model;

determining one or more semiconductor device manufacturing process parameter variations based on the detected variation in the semiconductor device manufacturing process; and

determining an adjustment for the semiconductor device manufacturing process based on the one or more determined semiconductor device manufacturing process parameter variations.

2. The method of clause 1, wherein the input information is for a stack associated with a semiconductor device.
3. The method of clause 2, wherein detecting variation in the semiconductor manufacturing process comprises predicting, with the machine learning prediction model, an overlay signal based on the output semiconductor device geometry variation.
4. The method of clause 2, wherein detecting variation in the semiconductor manufacturing process comprises predicting, with the machine learning prediction model, an alignment signal based on the output semiconductor device geometry variation.
5. The method of any of clauses 1-4, further comprising tuning the predicted output semiconductor device geometry variation, the tuning comprising comparing the output semiconductor device geometry variation to corresponding physical measurements and/or predictions from a different non machine learning prediction model, generating a loss function based on the comparison, and optimizing the loss function.
6. The method of any of clauses 1-5, wherein the geometry information comprises one or more dimensions of a target design for one or more layers of a semiconductor device.
7. The method of any of clauses 1-6, wherein the manufacturing process information comprises one or more etch process parameters, one or more deposition process parameters, and/or one or more chemical mechanical polishing process parameters.
8. The method of any of clauses 1-7, wherein the adjustment for the semiconductor device manufacturing process comprises one or more of:

a change in an etch process parameter from a first etch process parameter value to a second etch process parameter value;

a change in a deposition process parameter from a first deposition process parameter value to a second deposition process parameter value; or

a change in a chemical mechanical polishing process parameter from a first chemical mechanical polishing process parameter to a second chemical mechanical polishing process parameter value.

9. The method of any of clauses 1-8, wherein the detected variation in the semiconductor device manufacturing process comprises one or more of variation in processing parameters of the manufacturing process, variation in material properties of one or more materials used in the manufacturing process, or variation in optical properties of the one or more materials.
10. A method for predicting substrate geometry associated with a manufacturing process, the method comprising:

receiving input information including geometry information and manufacturing process information for a substrate; and

predicting, using a machine learning prediction model, output substrate geometry based on the input information.

11. The method of clause 10, wherein the substrate comprises a stack associated with a semiconductor device.
12. The method of any of clauses 10-11, further comprising tuning the predicted output substrate geometry, the tuning comprising comparing the output substrate geometry to corresponding physical substrate measurements and/or predictions from a different non machine learning prediction model, generating a loss function based on the comparison, and optimizing the loss function.
13. The method of clause 12, wherein the tuning comprises stack tuning, wherein:

stack tuning inputs comprise (1) a signal associated with a measurement from a corresponding physical stack, (2) the geometry information, the geometry information including nominal geometry of the physical stack, and (3) the manufacturing process information, and

a stack tuning output comprises the output substrate geometry,

and wherein the output substrate geometry is tuned such that a simulated signal determined based on the output substrate geometry corresponds to the signal associated with the measurement from the physical stack and/or the nominal geometry of the physical stack.

14. The method of any of clauses 10-13, further comprising predicting, with the machine learning prediction model, an overlay signal based on the output substrate geometry.
15. The method of any of clauses 10-13, further comprising predicting, with the machine learning prediction model, an alignment signal based on the output substrate geometry.
16. The method of any of clauses 10-15, wherein the machine learning prediction model comprises a neural network.
17. The method of any of clauses 10-16, wherein the geometry information comprises one or more dimensions of a target or mark design for one or more layers of a semiconductor device.
18. The method of any of clauses 10-17, wherein the manufacturing process information comprises one or more parameters for one or more manufacturing processes performed on one or more layers of a semiconductor device.
19. The method of any of clauses 10-18, further comprising training the machine learning prediction model with training information that describes geometry, pattern, and manufacturing process parameters for training substrates, and corresponding physical substrate measurements and/or predictions from a different non machine learning prediction model.
20. A method for monitoring performance of a manufacturing process, the method comprising:

receiving one or more input signals that convey information related to geometry of a substrate generated by the manufacturing process; and

determining, with a prediction model, variation in the manufacturing process based on the one or more input signals.

21. The method of clause 20, wherein the substrate is associated with a semiconductor device, and the manufacturing process comprises a semiconductor device manufacturing process.
22. The method of clause 21, further comprising determining an adjustment for a semiconductor device manufacturing apparatus based on the variation in the manufacturing process.
23. The method of any of clauses 21-22, wherein the receiving and the determining are performed in real time or near real time during the semiconductor device manufacturing process.
24. The method of any of clauses 20-23, wherein the one or more input signals comprise an overlay signal.
25. The method of any of clauses 20-24, wherein the one or more input signals comprise an alignment signal.
26. The method of any of clauses 20-25, wherein the variation in the manufacturing process comprises one or more of variation in processing parameters of the manufacturing process, variation in material properties of one or more materials used in the manufacturing process, or variation in optical properties of the one or more materials.
27. The method of any of clauses 18-26, wherein the prediction model comprises a machine learning model.
28. The method of any of clauses 18-27, wherein the prediction model comprises a neural network.
29. The method of any of clauses 18-28, wherein the substrate comprises a stack associated with a semiconductor device.
30. The method of any of clauses 18-29, further comprising training the prediction model based on known perturbations in the manufacturing process.
31. A computer program product comprising a non-transitory computer readable medium having instructions recorded thereon, the instructions when executed by a computer implementing the method of any of clauses 1-30 above.

While the concepts disclosed herein may be used for wafer manufacturing on a substrate such as a silicon wafer, it shall be understood that the disclosed concepts may be used with any type of manufacturing system, e.g., those used for manufacturing on substrates other than silicon wafers. In addition, the combination and sub-combinations of disclosed elements may comprise separate embodiments. For example, the method for predicting process variation and the method for tuning may comprise separate embodiments, and/or these methods may be used together in the same embodiment.

The descriptions above are intended to be illustrative, not limiting. Thus, it will be apparent to one skilled in the art that modifications may be made as described without departing from the scope of the claims set out below.

1. A method of predicting substrate geometry associated with a semiconductor manufacturing process, the method comprising:
receiving input information including geometry information and manufacturing process information for a substrate; and
predicting, using a machine learning prediction model, output substrate geometry based on the input information, wherein the substrate comprises a stack.

2. (canceled)

3. The method of claim 1, further comprising tuning the predicted output substrate geometry based on the predicting, the tuning comprising:
comparing the output substrate geometry to corresponding physical substrate measurements and/or predictions from a non-machine learning prediction model; and
generating a loss function based on the comparison; and
optimizing the loss function.

4. The method of claim 3, wherein the tuning comprises stack tuning, wherein:
stack tuning inputs comprise (1) a signal associated with a measurement from a corresponding physical stack, (2) the geometry information, the geometry information including nominal geometry of the physical stack, and (3) the manufacturing process information, and
a stack tuning output comprises the output substrate geometry.

5. The method of claim 4, wherein the output substrate geometry is tuned such that a simulated signal determined based on the output substrate geometry corresponds to the signal associated with the measurement from the physical stack and/or the nominal geometry of the physical stack.

6. The method of claim 1, further comprising predicting, using the machine learning prediction model, an overlay signal based on the output substrate geometry.

7. The method of claim 1, further comprising predicting, using the machine learning prediction model, an alignment signal based on the output substrate geometry.

8. (canceled)

9. The method of claim 1, wherein the geometry information comprises one or more dimensions of a target or mark design for one or more layers of a semiconductor device.

10. The method of claim 1, wherein the manufacturing process information comprises one or more parameters for one or more manufacturing processes performed on one or more layers of a semiconductor device.

11. The method of claim 1, further comprising training the machine learning prediction model with training information comprising geometry, pattern, and manufacturing process parameters for training substrates, and corresponding physical substrate measurements and/or predictions from a non-machine learning prediction model.

12. The method of claim 1, further comprising determining, with the prediction model, variation in a manufacturing process based on the input information.

13. The method of claim 12, further comprising determining an adjustment for a semiconductor device manufacturing apparatus based on the variation in the manufacturing process, wherein the determining the adjustment is performed in substantially real time with receiving an overlay signal and/or an alignment signal during the semiconductor device manufacturing process.

14. The method of claim 12, wherein the variation in the manufacturing process comprises one or more selected from: variation in one or more processing parameters of the manufacturing process, variation in one or more material properties of one or more materials used in the manufacturing process, or variation in one or more optical properties of the one or more materials.

15. The method of claim 11, wherein the training comprises training the prediction model based on known perturbations in the manufacturing process.

16. A computer program product comprising a non-transitory computer readable medium having instructions therein, the instructions, when executed by a computer system, configured to cause the computer system to implement the method of claim 1.

17. A method for monitoring performance of a manufacturing process, the method comprising:
receiving one or more input signals that convey information related to geometry of a substrate generated by the manufacturing process; and
determining, by a hardware computer using a prediction model, variation in the manufacturing process based on the one or more input signals, wherein the substrate is associated with a semiconductor device, and the manufacturing process comprises a semiconductor device manufacturing process.

18. The method of claim 17, further comprising determining an adjustment for a semiconductor device manufacturing apparatus based on the variation in the manufacturing process.

19. The method of claim 17, wherein the receiving and the determining are performed in real time or near real time during the semiconductor device manufacturing process.

20. The method of claim 17, wherein the one or more input signals comprise an overlay signal or an alignment signal.

21. The method of claim 17, wherein the variation in the manufacturing process comprises one or more selected from: variation in one or more processing parameters of the manufacturing process, variation in one or more material properties of one or more materials used in the manufacturing process, or variation in one or more optical properties of the one or more materials.

22. The method of claim 17, wherein the prediction model comprises a machine learning model.
